(19) United States
(12) Patent Application Publication
(10) Pub. No.: US 2024/0071725 A1
(43) Pub. Date: Feb. 29, 2024

(54) PLASMA APPARATUS AND METHODS FOR PROCESSING FEED MATERIAL UTIZILING A POWDER INGRESS PREVENTOR (PIP)

(71) Applicant: 6K Inc., North Andover, MA (US)

(72) Inventors: Michael C. Kozlowski, Reading, MA (US); Ed Petersen, Groveland, MA (US); John Colwell, Durham, NH (US); Anthony Andrew, Boston, MA (US)

(21) Appl. No.: 18/451,720

(22) Filed: Aug. 17, 2023

Related U.S. Application Data
(60) Provisional application No. 63/373,528, filed on Aug. 25, 2022.

(51) Int. Cl. H01J 37/32

(52) U.S. Cl. CPC H01J 37/32201; H01J 37/3244; H01J 37/32477; H01J 37/32642; H01J 2237/327

(57) ABSTRACT

Disclosed herein are systems, methods, and devices processing feed material utilizing a microwave plasma apparatus comprising a powder ingress preventor (PIP). In some embodiments, the microwave plasma apparatus comprises a core plasma tube and a liner; and a ring structure comprising: a bearing surface, the bearing surface contacting an interior diameter of the core plasma tube; and an opening, the opening contacting an outer diameter of the liner.

### INCORPORATION BY REFERENCE TO ANY PRIORITY APPLICATIONS

This application claims the priority benefit under 35 U.S.C. § 119(e) of U.S. Provisional Application No. 63/373,528, filed Aug. 25, 2022, the entire disclosure of which is incorporated herein by reference in its entirety. Any and all applications for which a foreign or domestic priority claim is identified in the Application Data Sheet as filed with the present application are hereby incorporated by reference under 37 CFR 1.57.

### BACKGROUND

### Field

The present invention relates to apparatuses and methods for plasma material processing and, more particularly, to apparatuses and methods for microwave plasma material processing.

### Description

Plasma torches generate and provide hot temperature directed flows of plasma for a variety of purposes. The two main types of plasma torches are induction plasma torches and microwave plasma torches. Generally, inductive plasmas suffer from plasma non-uniformity. This non-uniformity leads to limitations on the ability of inductive plasmas to process certain materials. Furthermore, significant differences exist between the microwave plasma apparatuses and other plasma generation torches, such as induction plasma. For example, microwave plasma is hotter on the interior of the plasma plume, while induction is hotter on the outside of the plumes. In particular, the outer region of an induction plasma can reach about 10,000 K while the inside processing region may only reach about 1,000 K. This large temperature difference leads to material processing and feeding problems. Furthermore, induction plasma apparatuses are unable to process feedstocks at low enough temperatures to avoid melting of certain feed materials without extinguishing the plasma.

A conventional microwave plasma apparatus for processing a material includes a plasma chamber, an applicator, a microwave radiation source, and a waveguide guiding microwave radiation from the microwave radiation source to the plasma chamber. A process gas flows through the plasma chamber and the microwave radiation couples to the process gas to produce a plasma jet. A process material is introduced to the plasma chamber, becomes entrained in the plasma jet, and is thereby transformed to a stream of product material droplets or particles.

In conventional microwave plasma apparatuses, normal pressure fluctuations in the plasma chamber can cause the process material to travel backwards into the applicator causing microwave arcing and plasma stability issues. Thus, novel plasma apparatuses and methods for processing materials are needed.

### SUMMARY

For purposes of this summary, certain aspects, advantages, and novel features of the invention are described herein. It is to be understood that not all such advantages necessarily may be achieved in accordance with any particular embodiment of the invention. Thus, for example, those skilled in the art will recognize that the invention may be embodied or conducted in a manner that achieves one advantage or group of advantages as taught herein without necessarily achieving other advantages as may be taught or suggested herein.

Some embodiments herein are directed to a microwave plasma apparatus for processing a material, comprising: a core plasma tube; a liner located within and concentric with the core plasma tube; a plasma applicator; and a ring structure located between the core plasma tube and the liner, the ring structure concentric with the core plasma tube and the liner, and the ring structure comprising: a bearing surface, the bearing surface contacting a bottom surface of the plasma applicator; and an opening, the opening surrounding the liner and having a diameter greater than an outer diameter of the liner.

In some embodiments, the ring structure is formed of glass or quartz. In some embodiments, the ring structure comprises a single piece of material. In some embodiments, the ring structure comprises an assembly comprising two or more pieces. In some embodiments, the assembly comprises a first piece comprising a flange and a second piece comprising a tube.

In some embodiments, the ring structure comprises a washer. In some embodiments, the washer comprises a plurality of holes. In some embodiments, the plurality of holes form one or more concentric circles on a surface of the washer. In some embodiments, the ring structure comprises a stack of washers. In some embodiments, the ring structure comprises a stack of two washers, three washers, or four washers.

In some embodiments, the opening comprises one or more indentations or serrations.

In some embodiments, the ring structure comprises an inverted cone. In some embodiments, the inverted cone comprises a rim, the rim comprising one or more holes formed through the rim. In some embodiments, the inverted cone comprises a serrated bottom opening.

Some embodiments herein are directed to a ring structure for preventing powder ingress within a microwave plasma apparatus, the ring structure comprising: a bearing surface, the bearing surface contacting a lower surface of a plasma applicator of the microwave plasma apparatus; and an opening, the opening the opening surrounding a liner of the microwave plasma apparatus and having a diameter greater than an outer diameter of the liner.

In some embodiments, the ring structure is formed of glass or quartz. In some embodiments, the ring structure comprises a single piece of material. In some embodiments, the ring structure comprises an assembly comprising two or more pieces. In some embodiments, the assembly comprises a first piece comprising a flange and a second piece comprising a tube.

In some embodiments, the ring structure comprises a washer. In some embodiments, the washer comprises a plurality of holes. In some embodiments, the plurality of holes form one or more concentric circles on a surface of the washer. In some embodiments, the ring structure comprises a stack of washers. In some embodiments, the ring structure comprises a stack of two washers, three washers, or four washers.

In some embodiments, the opening comprises one or more indentations or serrations.

In some embodiments, the ring structure comprises an inverted cone. In some embodiments, the inverted cone comprises a rim, the rim comprising one or more holes formed through the rim. In some embodiments, the inverted cone comprises a serrated bottom opening.

### BRIEF DESCRIPTION OF THE DRAWINGS

The drawings are provided to illustrate example embodiments and are not intended to limit the scope of the disclosure. A better understanding of the systems and methods described herein will be appreciated upon reference to the following description in conjunction with the accompanying drawings, wherein:

FIG. 1 illustrates an example microwave plasma torch 100 that can be used in the processing of feed material materials.

FIGS. 2A-B illustrates an exemplary microwave plasma torch that includes a side feeding hopper, thus allowing for downstream feeding.

FIG. 3 illustrates an isometric view of an example powder ingress preventor according to some embodiments herein.

FIG. 4 illustrates a side view of the example powder ingress preventor of FIG. 3.

FIG. 5 illustrates a bottom view of the example powder ingress preventor of FIG. 3.

FIG. 6 illustrates an isometric view of another example powder ingress preventor according to some embodiments herein.

FIG. 7 illustrates a side view of the example powder ingress preventor of FIG. 6.

FIG. 8 illustrates a bottom view of the example powder ingress preventor of FIG. 6.

FIG. 9 is an image of the example powder ingress preventor of FIG. 6.

FIG. 10 illustrates another example powder ingress preventor according to some embodiments herein.

FIG. 11 illustrates another example powder ingress preventor according to some embodiments herein.

FIG. 12 illustrates another example powder ingress preventor according to some embodiments herein.

FIG. 13 illustrates another example powder ingress preventor according to some embodiments herein.

FIG. 14 illustrates another example powder ingress preventor according to some embodiments herein.

FIG. 15 illustrates a side view of the example powder ingress preventor of FIG. 14.

FIG. 16A-16C illustrate an example microwave plasma apparatus comprising a powder ingress preventor according to some embodiments herein.

FIG. 17 illustrates an example microwave plasma apparatus comprising a waveguide and plasma applicator with a powder ingress preventor according to some embodiments herein.

FIG. 18 illustrates an example microwave plasma apparatus comprising a waveguide and plasma applicator with a powder ingress preventor according to some embodiments herein.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto or as presented in the future is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be conducted in a manner that achieves or optimizes one advantage or group of advantages as taught herein without necessarily achieving other aspects or advantages as may also be taught or suggested herein.

Certain exemplary embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present technology.

Some embodiments herein are directed to microwave plasma apparatus and methods for processing materials using a microwave plasma apparatus comprising a powder ingress preventor (PIP). In some embodiments, the PIP creates a barrier between the reaction/plasma chamber and the applicator, blocking or collecting powder before it can reach the applicator. In conventional microwave plasma apparatuses, normal pressure fluctuations in the plasma chamber can cause the process material to travel backwards into the applicator causing microwave arcing and plasma stability issues. In some embodiments, the PIP may comprise a barrier between the reaction chamber and the applicator, preventing process material from reaching the applicator. In some embodiments, the PIP completely or at least partially prevents processing material that has reached the reaction chamber from entering the applicator. In some embodiments, the PIP not only deters powder from reaching the applicator, but also collects powder along its entire inner surface. In some embodiments, the PIP may comprise one or more of a filter, shield, collector, tube, washer, cover, and/or other protection device or widget. In some embodiments, the PIP may comprise a quartz sleeve piece laying in the applicator around the liner.

In a conventional apparatus, the applicator, a pressure window, or liner may be dirtied or damaged by material build-up returning from the reaction chamber. Waveguide pressure windows are a type of seal used to prevent contaminants (e.g., moisture, dirt, processing material and dust) from entering the waveguide that transmits microwaves from the microwave generator to the applicator. The pressure window may also isolate pressurized sections of the apparatus from non-pressurized sections of the apparatus. For example, the pressure window can be used to seal waveguides when pressurization or gas filling is required. Waveguide pressure windows enable the signal to pass through but block atmospheric gases or contaminants from getting through. If the pressure window is dirtied or damaged, microwave power transmission may be compromised and pressure imbalance in the apparatus may occur. The liner may comprise an interior surface material or coating in the reaction chamber or core plasma tube that protects the interior wall of the apparatus from heat and processing materials. Damage to the liner may compromise the structural integrity of the microwave plasma apparatus.

To prevent dirtying or damaging the applicator, the pressure window, and/or the liner, the microwave plasma apparatus may be manually cleaned after every use. However, in some embodiments, the utilization of a PIP within a microwave plasma apparatus may prevent material build-up on the interior of or on an exterior surface of the plasma applicator, on a pressure window, or on a liner of the microwave plasma apparatus. Thus, in some embodiments, cleaning of the microwave plasma apparatus may be avoided after each run, increasing uptime of the apparatus, such that throughput is increased.

In a conventional apparatus, the buildup of processing materials may be characterized as either “wet” or “dry.” The buildup may be wet when a waveguide gas is not utilized. When waveguide gas is used, such as waveguide gas at a flow rate of about 3 scfm, there may be a dry buildup of processing materials. Waveguide gas is purging gas (typically Ar or N2) that enters the system from the pressure-window assembly and flows directly into the applicator. The gas is injected from the top of the pressure-window assembly, vertically, and/or tangent to the pressure-window. The gas exits the applicator through the lower neck and into the reactor, around the outer diameter of the torch liner. There are two main reasons for using waveguide gas, including keeping buildup off of the pressure window and out of the applicator, and providing a small amount of cooling to the torch liner. In some embodiments, the use of a PIP may prevent wet buildup or dry buildup in a microwave plasma apparatus.

In some embodiments, various design considerations must be accounted for in designing and utilizing a PIP for use in a microwave plasma apparatus. For example, pressure fluctuations from a bag house of the apparatus, extreme heat from the plasma, and microwave interference may all inhibit proper functioning of the PIP. In some embodiments, the PIP utilized according to some embodiments herein may be designed and utilized to withstand pressure fluctuations, extreme heat, and microwave interference. In some embodiments, the PIP is designed with an elongated shape (e.g., instead of being a simple washer). In some embodiments, this design adds weight to the PIP to make it heavier, such that the PIP does not move and/or break during large positive pressure fluctuations. In some embodiments, even if the PIP does move, a long bearing surface may be provided so the PIP does not settle unevenly in the apparatus. In some embodiments, the PIP is made from a single piece of quartz glass. Due to the material properties of quartz glass, the PIP is transparent to microwave radiation (does not absorb or have any significant effect on field characteristics) and can withstand elevated temperature environments.

In conventional microwave plasma apparatuses, powder ingress can introduce various problems in plasma applications. For example, powder ingress can cause issues connected to the pressure window and cause other plasma torch instabilities. In some embodiments, utilizing a PIP may maximize reduction of incidence to a microwave plasma and plasma applicator by powder ingress.

In some embodiments, the PIP may comprise a tube structure and a bearing structure. In some embodiments, a bearing surface, or area of contact between the bearing structure and an interior surface of the microwave plasma torch may be maximized. In some embodiments, maximizing the bearing surface may prevent or mitigate the risk of displacement or disturbance of the PIP due to a pressure spike in the microwave plasma apparatus. In some embodiments, the bag house of the microwave plasma apparatus may occasionally deliver a pressure spike to the system. If a PIP in the form of, for example, a quartz washer was placed around the liner in the plasma applicator, it would have an area exposed to this pressure wave. If the PIP is displaced by the pressure wave, the PIP could fall non-concentrically and cause the liner to be damaged or crack. Thus, in some embodiments, the PIP must be designed in such a way to avoid displacement by pressure spikes or other environmental forces in the system. In some embodiments, the pressure around the plasma application may be about 650 Torr but may rise to at least 700 Torr for about 0.1 s during a pressure spike. In some embodiments, the bearing surface, or the incident area may comprise a solid annulus between the interior diameter of the lower neck/applicator of the core plasma tube of the microwave plasma apparatus, and the outer diameter of the liner covering the core plasma tube.

In some embodiments, the interior diameter of the lower neck/applicator of the core plasma tube may be about 101.6 mm. In some embodiments, the interior diameter of the lower neck/applicator of the core plasma tube may be about mm, about 30 mm, about 55 mm, about 80 mm, about 105 mm, about 130 mm, about 155 mm, about 180 mm, about 205 mm, about 230 mm, about 255 mm, about 280 mm, about 305 mm, about 330 mm, about 355 mm, about 380 mm, about 405 mm, about 430 mm, about 455 mm, about 480 mm, about 500 mm, or any value between the aforementioned values.

In some embodiments, the outer diameter of the liner covering the core plasma tube may be about 77 mm. In some embodiments, the outer diameter of the liner covering the core plasma tube may be about 5 mm, about 30 mm, about 55 mm, about 80 mm, about 105 mm, about 130 mm, about 155 mm, about 180 mm, about 205 mm, about 230 mm, about 255 mm, about 280 mm, about 305 mm, about 330 mm, about 355 mm, about 380 mm, about 405 mm, about 430 mm, about 455 mm, about 480 mm, about 500 mm, or any value between the aforementioned values.

In some embodiments, the area of the exposed annulus may be about 3116.1 mm. In some embodiments, the area of the exposed annulus may comprise the area subjected to the pressure wave/spike/impulse. In some embodiments, the area of the exposed annulus may be about 1000 mm, about 1100 mm, about 1200 mm, about 1300 mm, about 1400 mm, about 1500 mm, about 1600 mm, about 1700 mm, about 1800 mm, about 1900 mm, about 2000 mm, about 2100 mm, about 2200 mm, about 2300 mm, about 2400 mm, about 2500 mm, about 2600 mm, about 2700 mm, about 2800 mm, about 2900 mm, about 3000 mm, about 3100 mm, about 3200 mm, about 3300 mm, about 3400 mm, about 3500 mm, about 3600 mm, about 3700 mm, about 3800 mm, about 3900 mm, about 4000 mm, about 4100 mm, about 4200 mm, about 4300 mm, about 4400 mm, about 4500 mm, about 4600 mm, about 4700 mm, about 4800 mm, about 4900 mm, about 5000 mm, or any value between the aforementioned values.

In some embodiments, the resultant force of a pressure spike may be about 4.8 lbs. In some embodiments, the resultant force of a pressure spike may be about 0.5 lbs., about 1 lbs., about 1.5 lbs., about 2 lbs., about 2.5 lbs., about 3 lbs., about 3.5 lbs., about 4 lbs., about 4.5 lbs., about 5 lbs., about 5.5 lbs., about 6 lbs., about 6.5 lbs., about 7 lbs., about 7.5 lbs., about 8 lbs., about 8.5 lbs., about 9 lbs., about 9.5 lbs., about 10 lbs., about 10.5 lbs., about 11 lbs., about 11.5 lbs., about 12 lbs., about 12.5 lbs., about 13 lbs., about 13.5 lbs., about 14 lbs., about 14.5 lbs., about 15 lbs., about 15.5 lbs., about 16 lbs., about 16.5 lbs., about 17 lbs., about 17.5 lbs., about 18 lbs., about 18.5 lbs., about 19 lbs., about 19.5 lbs., about 20 lbs., about 20.5 lbs., about 21 lbs., about 21.5 lbs., about 22 lbs., about 22.5 lbs., about 23 lbs., about 23.5 lbs., about 24 lbs., about 24.5 lbs., about 25 lbs., or any value between the aforementioned values.

In some embodiments, the time length of a pressure spike may be about 0.1 s. In some embodiments, the time length of a pressure spike may be about 0.01 s, about 0.02 s, about 0.03 s, about 0.04 s, about 0.05 s, about 0.06 s, about 0.07 s, about 0.08 s, about 0.09 s, about 0.1 s, about 0.11 s, about 0.12 s, about 0.13 s, about 0.14 s, about 0.15 s, about 0.16 s, about 0.17 s, about 0.18 s, about 0.19 s, about 0.2 s, about 0.21 s, about 0.22 s, about 0.23 s, about 0.24 s, about 0.25 s, or any value between the aforementioned values.

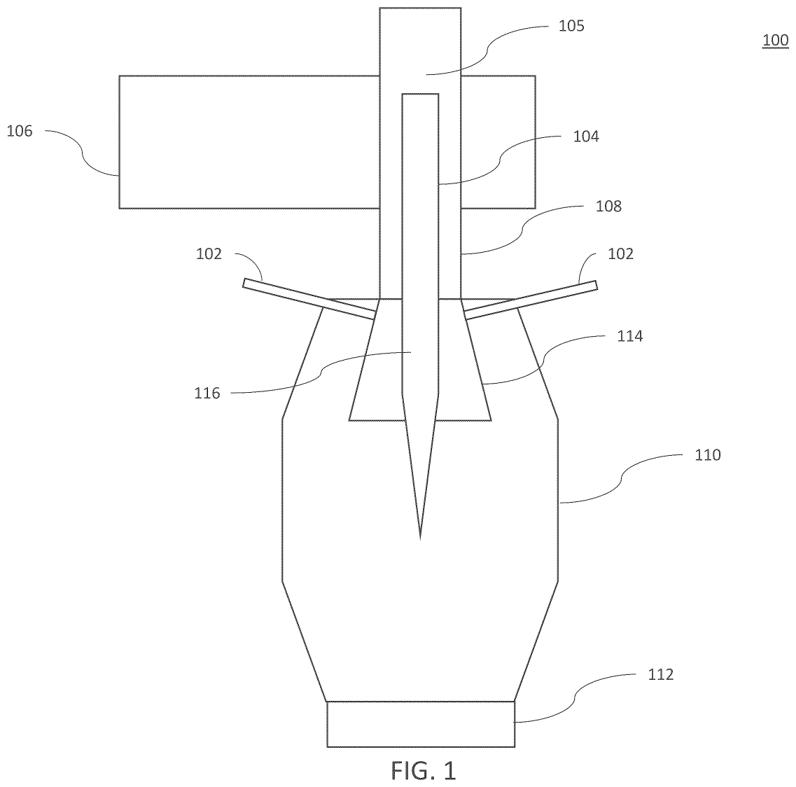

FIG. 1 illustrates an example microwave plasma torch 100 that can be used in the production of materials. In some embodiments, a feedstock can be introduced, via one or more feedstock inlets 102, into a microwave plasma 104. In some embodiments, an entrainment gas flow and/or a sheath flow may be injected into the microwave plasma applicator 105 to create flow conditions within the plasma applicator prior to ignition of the plasma 104 via microwave radiation source 106. In some embodiments, the entrainment flow and sheath flow are both axis-symmetric and laminar, while in other embodiments the gas flows are swirling. In some embodiments, the feedstock may be introduced into the microwave plasma torch 100, where the feedstock may be entrained by a gas flow that directs the materials toward the plasma 104.

In some embodiments, within the microwave plasma 104, the feedstock may undergo a physical and/or chemical transformation. Inlets 102 can be used to introduce process gases to entrain and accelerate the feedstock towards plasma 104. In some embodiments, a second swirling gas flow can be created to provide sheathing for the inside wall of a plasma applicator 104 and a reaction chamber 110 to protect those structures from melting due to heat radiation from plasma 104.

Various parameters of microwave plasma 104, as created by the plasma applicator 105, may be adjusted manually or automatically in order to achieve a desired material. These parameters may include, for example, power, plasma gas flow rates, type of plasma gas, presence of an extension tube, extension tube material, level of insulation of the reactor chamber or the extension tube, level of coating of the extension tube, geometry of the extension tube (e.g. tapered/stepped), feed material size, feed material insertion rate, feed material inlet location, feed material inlet orientation, number of feed material inlets, plasma temperature, residence time and cooling rates. The resulting material may exit the plasma into sealed chamber 112 where the material is quenched then collected.

In some embodiments, the feedstock is injected after the microwave plasma applicator for processing in the “plume” or “exhaust” of the microwave plasma torch. Thus, the plasma of the microwave plasma torch is engaged at the exit end of the plasma torch core tube 108, or further downstream. In some embodiments, adjustable downstream feeding allows engaging the feedstock with the plasma plume downstream at a temperature suitable for optimal melting of feedstock through precise targeting of temperature level and residence time. Adjusting the inlet location and plasma characteristics may allow for further customization of material characteristics. Furthermore, in some embodiments, by adjusting power, gas flow rates, pressure, and equipment configuration (e.g., introducing an extension tube), the length of the plasma plume may be adjusted.

In some embodiments, feeding configurations may include one or more individual feeding nozzles surrounding the plasma plume. The feedstock may enter the plasma from any direction and can be fed in 360° around the plasma depending on the placement and orientation of the inlets 102. Furthermore, the feedstock may enter the plasma at a specific position along the length of the plasma 104 by adjusting placement of the inlets 102, where a specific temperature has been measured and a residence time estimated for providing the desirable characteristics of the resulting material.

In some embodiments, the angle of the inlets 102 relative to the plasma 104 may be adjusted, such that the feedstock can be injected at any angle relative to the plasma 104. In some embodiments, implementation of the downstream injection method may use a downstream swirl or quenching. A downstream swirl refers to an additional swirl component that can be introduced downstream from the plasma applicator to keep the powder from the walls of the applicator 105, the reactor chamber 110, and/or an extension tube 114.

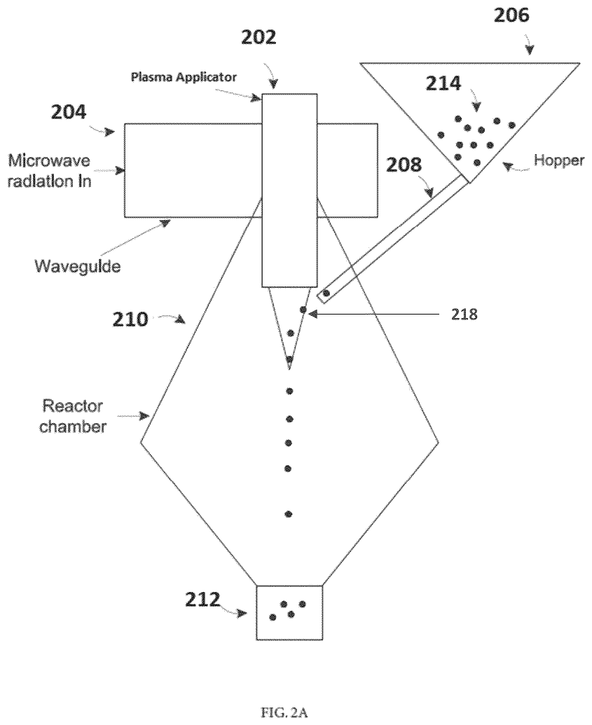

FIGS. 2A-B illustrates an exemplary microwave plasma torch that includes a side feeding hopper, thus allowing for downstream feeding. Thus, in this implementation the feedstock is injected after the microwave plasma torch applicator for processing in the “plume” or “exhaust” of the microwave plasma torch. Thus, the plasma of the microwave plasma torch is engaged at the exit end of the plasma torch to allow downstream feeding of the feedstock, as opposed to the top-feeding (or upstream feeding). This downstream feeding can advantageously extend the lifetime of the torch as the hot zone is preserved indefinitely from any material deposits on the walls of the hot zone liner. Furthermore, it allows engaging the plasma plume downstream at temperature suitable for optimal melting of powders through precise targeting of temperature level and residence time. For example, there is the ability to dial the length of the plume using microwave powder, gas flows, and pressure in the quenching vessel that contains the plasma plume.

Generally, the downstream feeding can utilize two main hardware configurations to establish a stable plasma plume which are: annular torch, such as described in U.S. Pat. Pub. No. 2018/0297122, the entirety of which is hereby incorporated by reference, or swirl torches described in U.S. Pat. No. 8,748,785 B2 and U.S. Pat. No. 9,932,673 B2, the entireties of which are hereby incorporated by reference. A feed system close-coupled with the plasma plume at the exit of the plasma torch is used to feed powder axisymmetrically to preserve process homogeneity.

Other feeding configurations may include one or several individual feeding nozzles surrounding the plasma plume. The feedstock powder can enter the plasma at a point from any direction and can be fed in from any direction, 360° around the plasma, into the point within the plasma. The feedstock powder can enter the plasma at a specific position along the length of the plasma plume where a specific temperature has been measured and a residence time estimated for sufficient melting of the particles. The melted particles exit the plasma into a sealed chamber where they are quenched then collected.

The feed materials 214 can be introduced into a microwave plasma applicator 202. Hopper 206 can be used to store the feed material 214 before feeding the feed material 214 into the microwave plasma applicator 202, plume and/or exhaust 218. The feed material 214 can be injected at any angle to the longitudinal direction of the plasma applicator 302. 5, 10, 15, 20, 25, 30, 35, 40, 45, 50, or 55 degrees. In some embodiments, the feedstock can be injected at an angle of greater than 5, 10, 15, 20, 25, 30, 35, 40, 45, 50, or 55 degrees. In some embodiments, the feedstock can be injected at an angle of less than 5, 10, 15, 20, 25, 30, 35, 40, 45, 50, or 55 degrees. In alternative embodiments, the feedstock can be injected along the longitudinal axis of the plasma torch.

The microwave radiation can be brought into the plasma applicator 202 through a waveguide 204. The feed material 214 is fed into a plasma chamber 210 and is placed into contact with the plasma generated by the plasma applicator 202. When in contact with the plasma, plasma plume, or plasma exhaust 218, the feed material melts. While still in the plasma chamber 210, the feed material 214 cools and solidifies before being collected into a container 212. Alternatively, the feed material 214 can exit the plasma chamber 210 through the outlet 212 while still in a melted phase and cool and solidify outside the plasma chamber. In some embodiments, a quenching chamber may be used, which may or may not use positive pressure. While described separately from FIG. 1, the embodiments of FIGS. 2A and 2B are understood to use similar features and conditions to the embodiment of FIG. 1.

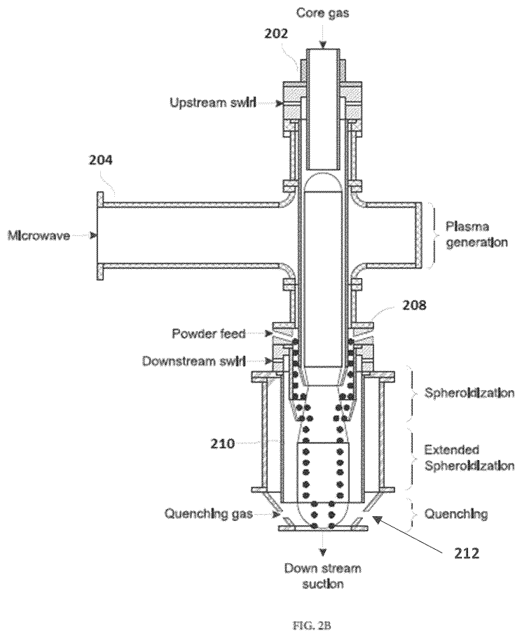

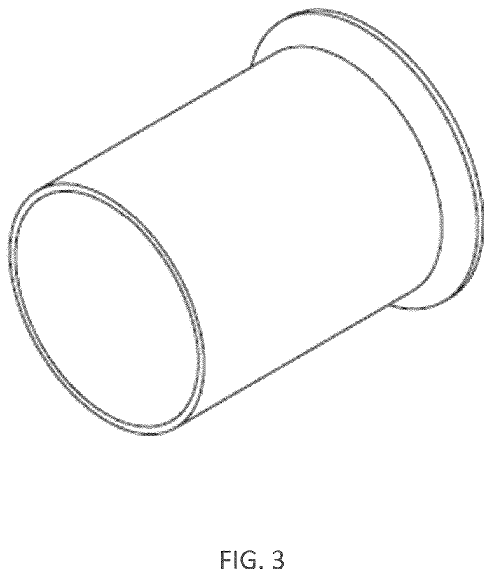

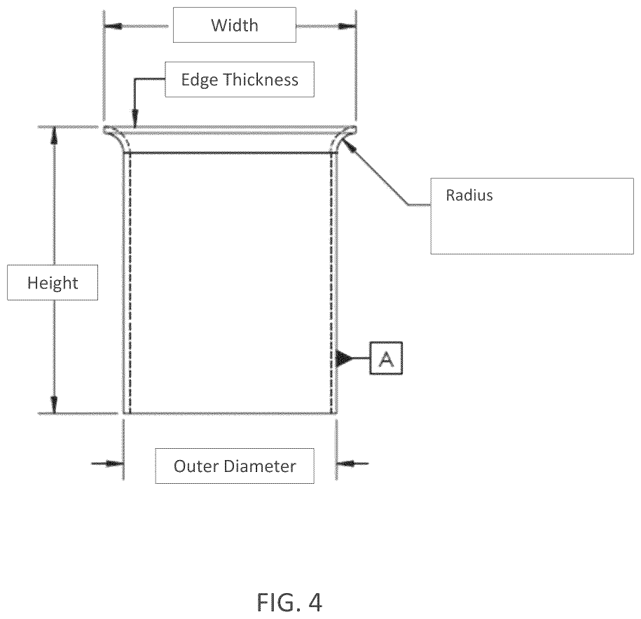

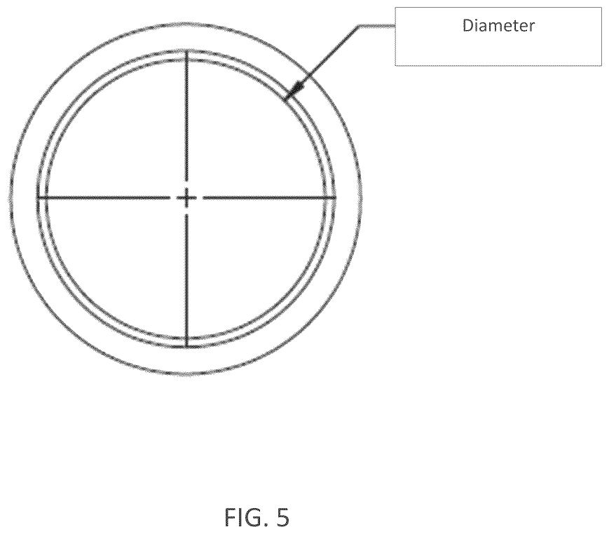

FIG. 3 illustrates an isometric view of an example powder ingress preventor according to some embodiments herein. FIG. 4 illustrates a side view of the example powder ingress preventor of FIG. 3. FIG. 5 illustrates a bottom view of the example powder ingress preventor of FIG. 3.

In some embodiments, the PIP may comprise an assembly comprising a flange (or washer) and a tube. Applicators of different types and manufacturers have different radii on the liner feedthrough. The PIP of FIGS. 3-5 is configured to fit in applicators of all types. For example, the PIP may be dimensioned such that it will fit and self-center in any applicator.

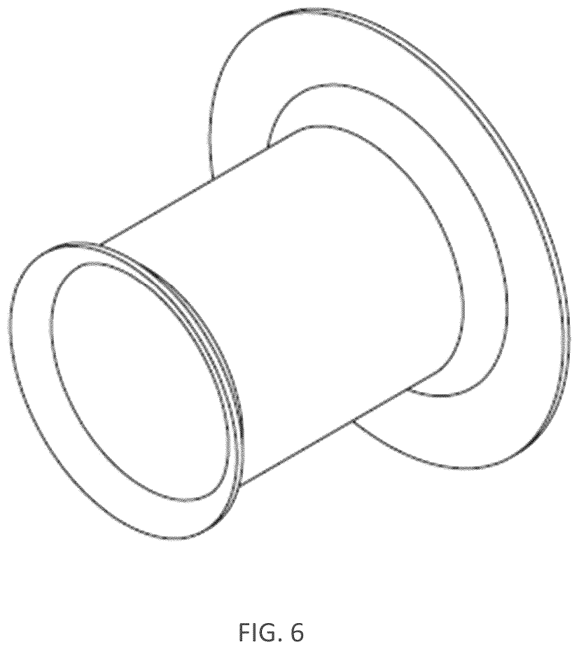

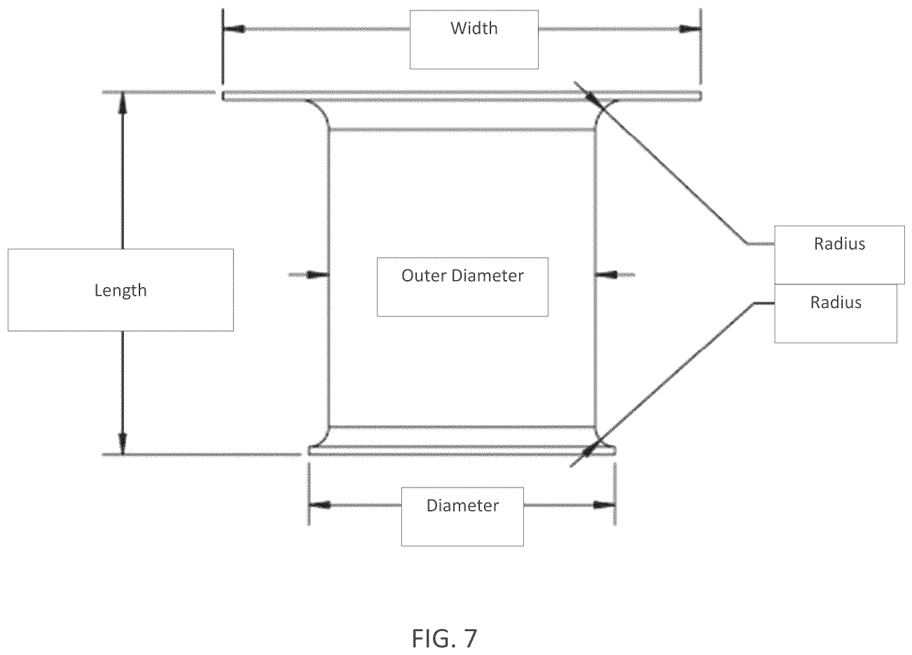

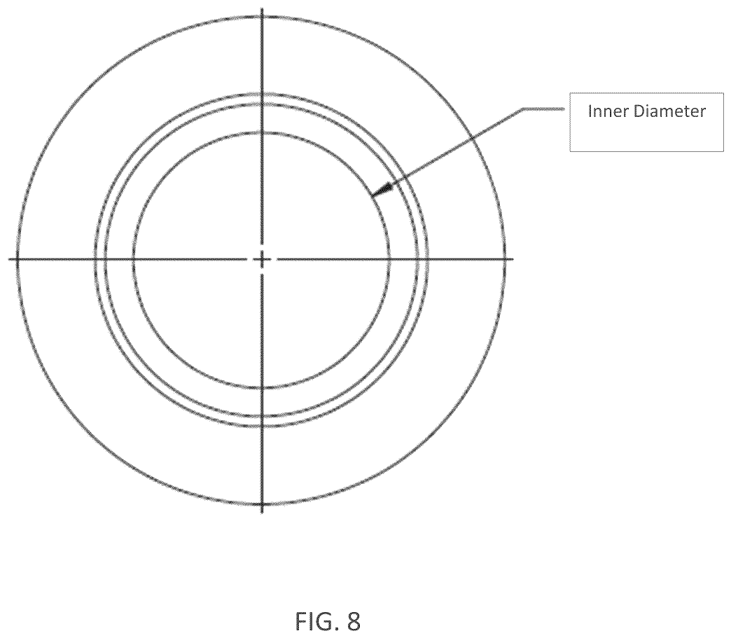

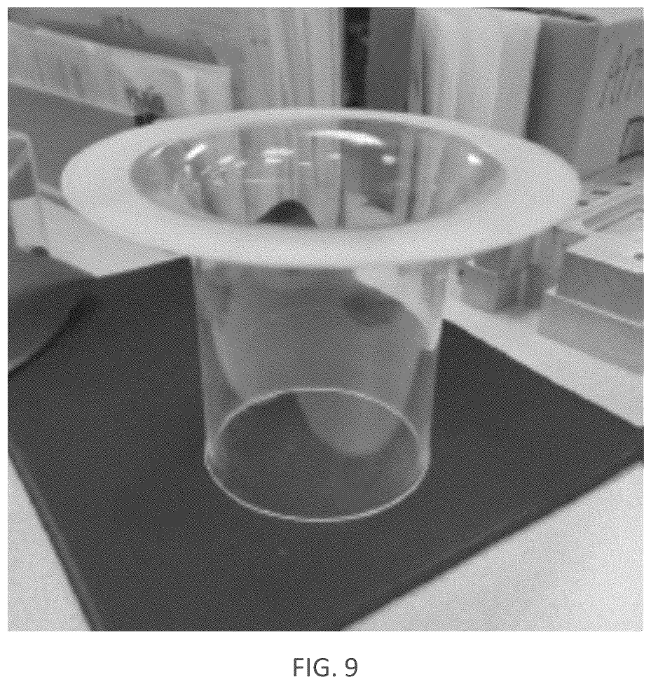

FIG. 6 illustrates an isometric view of another example powder ingress preventor according to some embodiments herein. FIG. 7 illustrates a side view of the example powder ingress preventor of FIG. 6. FIG. 8 illustrates a bottom view of the example powder ingress preventor of FIG. 6. FIG. 9 is an image of the example powder ingress preventor of FIG. 6.

In some embodiments, a PIP may comprise a quartz glass tube. In some embodiments, the PIP may comprise a single, monolithic piece of tube, which may be flared by a glassmaker. In some embodiments, the PIP may comprise a tube portion and a washer portion, wherein the washer portion comprises a bearing surface that contacts the core tube and/or liner of the microwave plasma apparatus. In some embodiments, the PIP may comprise an increased bearing surface, to prevent displacement of the PIP into to the liner. In some embodiments, the geometry of the PIP may add weight while minimizing incidence to the microwave.

In some embodiments, the PIP may comprise a glass-blown part comprising a quartz tube. In some embodiments, the PIP displacement from a worst-case pressure fluctuation may be about 0.426 inches. In some embodiments, the PIP may comprise an increased bearing surface and flared ends to prevent catching on the plasma core tube liner during displacement. In some embodiments, a one-piece, monolithic PIP may be advantageous as there is less risk of the pieces coming apart during pressure fluctuations.

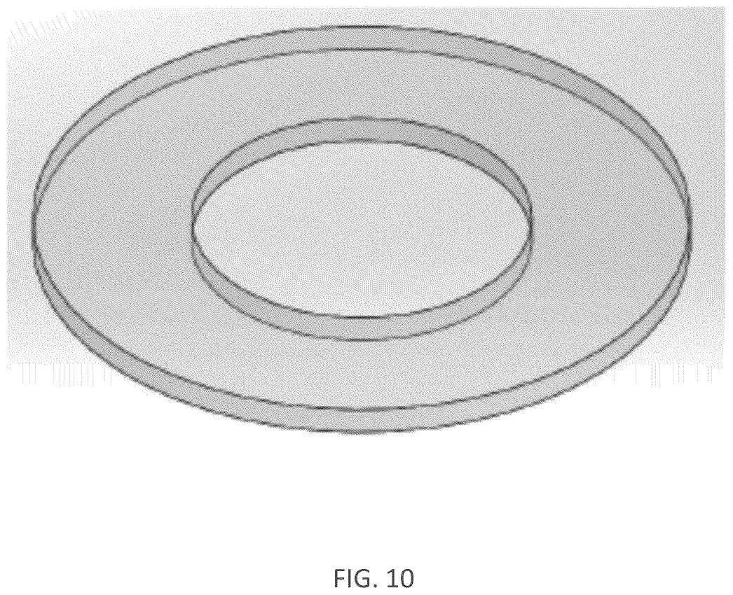

FIG. 10 illustrates another example powder ingress preventor according to some embodiments herein. In some embodiments, the PIP may comprise a washer. In some embodiments, the washer may be formed from quartz. In some embodiments, the PIP may comprise a stack of two or more washers. In some embodiments, the PIP may comprise a stack of 2, a stack of 3 washers, or a stack of 4 washers. In some embodiments, the PIP may comprise a larger stack of washers, such as a stack of 5 washers, 10 washers, 15 washers, 20 washers, 25 washers, or any value between the aforementioned values.

In some embodiments, the PIP may comprise an outer diameter and an opening comprising an inner diameter. In some embodiments, the outer diameter may be about 6 inches. In some embodiments, the outer diameter may be about 0.5 inches, about 1 inches, about 1.5 inches, about 2 inches, about 2.5 inches, about 3 inches, about 3.5 inches, about 4 inches, about 4.5 inches, about 5 inches, about 5.5 inches, about 6 inches, about 6.5 inches, about 7 inches, about 7.5 inches, about 8 inches, about 8.5 inches, about 9 inches, about 9.5 inches, about 10 inches, about 10.5 inches, about 11 inches, about 11.5 inches, about 12 inches, about 12.5 inches, or any value between the aforementioned values.

In some embodiments, the PIP may comprise an inner diameter of about 3.138 inches. In some embodiments, the inner diameter may be about 0.25 inches, about 0.75 inches, about 1.25 inches, about 1.75 inches, about 2.25 inches, about 2.75 inches, about 3.25 inches, about 3.75 inches, about 4.25 inches, about 4.75 inches, about 5.25 inches, about 5.75 inches, about 6.25 inches, about 6.75 inches, about 7.25 inches, about 7.75 inches, about 8.25 inches, about 8.75 inches, about 9.25 inches, about 9.75 inches, about 10.25 inches, about 10.75 inches, about 11.25 inches, about 11.75 inches, about 12.25 inches, or any value between the aforementioned values.

In some embodiments, the PIP may comprise a thickness of about 0.25 inches. In some embodiments, the PIP may comprise a thickness of about 0.05 inches, about 0.1 inches, about 0.15 inches, about 0.2 inches, about 0.25 inches, about 0.3 inches, about 0.35 inches, about 0.4 inches, about 0.45 inches, about 0.5 inches, about 0.55 inches, about 0.6 inches, about 0.65 inches, about 0.7 inches, about 0.75 inches, about 0.8 inches, about 0.85 inches, about 0.9 inches, about 0.95 inches, about 1 inches, about 1.05 inches, about 1.1 inches, about 1.15 inches, about 1.2 inches, about 1.25 inches, about 1.3 inches, about 1.35 inches, about 1.4 inches, about 1.45 inches, about 1.5 inches, about 1.55 inches, about 1.6 inches, about 1.65 inches, about 1.7 inches, about 1.75 inches, about 1.8 inches, about 1.85 inches, about 1.9 inches, about 1.95 inches, about 2 inches, about 2.05 inches, about 2.1 inches, about 2.15 inches, about 2.2 inches, about 2.25 inches, about 2.3 inches, about 2.35 inches, about 2.4 inches, about 2.45 inches, about 2.5 inches, or any value between the aforementioned values.

In some embodiments, a worst-case displacement caused by pressure fluctuation may be about 0.236 inches for a stack of 2 washers, about 0.137 inches for a stack of 3 washers, and about 0.087 inches for stack of 4 washers. In some embodiments, a washer PIP design may be immediately sourced, have low deflection for larger stacks of washers, and advantageously create a minimal gap around the liner.

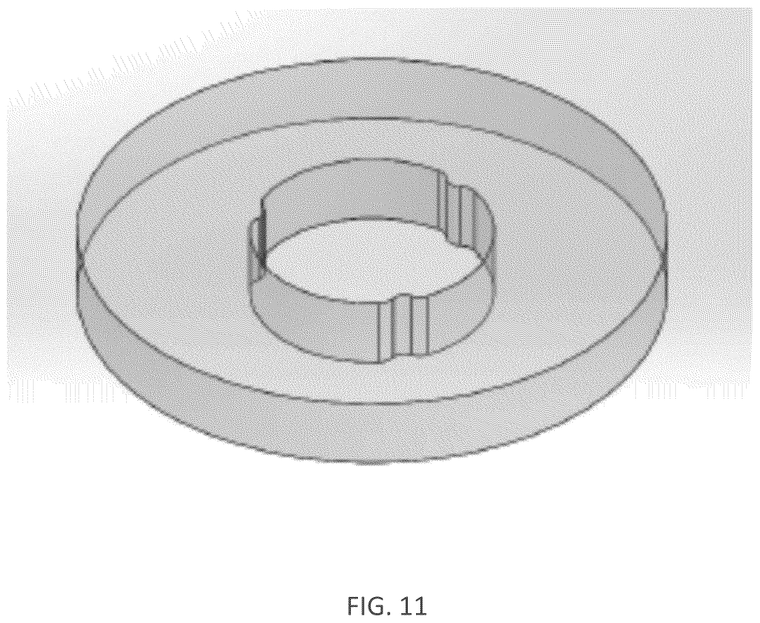

FIG. 11 illustrates another example powder ingress preventor according to some embodiments herein. In some embodiments, the PIP may comprise a machined washer comprising quartz. In some embodiments, the washer may be thicker to prevent deflection during pressure fluctuations. In some embodiments, the PIP may comprise one or more centering features along the inner diameter of the washer to assist with centering the washer in the core plasma tube. In some embodiments, the centering features may comprise structures or indentations on the interior diameter. In some embodiments, the centering features may also prevent or mitigate overheating of the washer. In some embodiments, machined PIPs may be manufactured to create a small or nonexistent gap between the PIP and interior wall of the core tube.

In some embodiments, the PIP may comprise a stack of two or more washers. In some embodiments, the PIP may comprise a stack of 2, a stack of 3 washers, or a stack of 4 washers. In some embodiments, the PIP may comprise a larger stack of washers, such as a stack of 5 washers, 10 washers, 15 washers, 20 washers, 25 washers, or any value between the aforementioned values.

In some embodiments, the PIP may comprise an outer diameter and an opening comprising an inner diameter. In some embodiments, the outer diameter may be about 6 inches. In some embodiments, the outer diameter may be about 0.5 inches, about 1 inches, about 1.5 inches, about 2 inches, about 2.5 inches, about 3 inches, about 3.5 inches, about 4 inches, about 4.5 inches, about 5 inches, about 5.5 inches, about 6 inches, about 6.5 inches, about 7 inches, about 7.5 inches, about 8 inches, about 8.5 inches, about 9 inches, about 9.5 inches, about 10 inches, about 10.5 inches, about 11 inches, about 11.5 inches, about 12 inches, about 12.5 inches, or any value between the aforementioned values.

In some embodiments, the PIP may comprise an inner diameter of about 3.138 inches. In some embodiments, the inner diameter may be about 0.25 inches, about 0.75 inches, about 1.25 inches, about 1.75 inches, about 2.25 inches, about 2.75 inches, about 3.25 inches, about 3.75 inches, about 4.25 inches, about 4.75 inches, about 5.25 inches, about 5.75 inches, about 6.25 inches, about 6.75 inches, about 7.25 inches, about 7.75 inches, about 8.25 inches, about 8.75 inches, about 9.25 inches, about 9.75 inches, about 10.25 inches, about 10.75 inches, about 11.25 inches, about 11.75 inches, about 12.25 inches, or any value between the aforementioned values.

In some embodiments, the PIP may comprise a thickness of about 0.25 inches. In some embodiments, the PIP may comprise a thickness of about 0.05 inches, about 0.1 inches, about 0.15 inches, about 0.2 inches, about 0.25 inches, about 0.3 inches, about 0.35 inches, about 0.4 inches, about 0.45 inches, about 0.5 inches, about 0.55 inches, about 0.6 inches, about 0.65 inches, about 0.7 inches, about 0.75 inches, about 0.8 inches, about 0.85 inches, about 0.9 inches, about 0.95 inches, about 1 inches, about 1.05 inches, about 1.1 inches, about 1.15 inches, about 1.2 inches, about 1.25 inches, about 1.3 inches, about 1.35 inches, about 1.4 inches, about 1.45 inches, about 1.5 inches, about 1.55 inches, about 1.6 inches, about 1.65 inches, about 1.7 inches, about 1.75 inches, about 1.8 inches, about 1.85 inches, about 1.9 inches, about 1.95 inches, about 2 inches, about 2.05 inches, about 2.1 inches, about 2.15 inches, about 2.2 inches, about 2.25 inches, about 2.3 inches, about 2.35 inches, about 2.4 inches, about 2.45 inches, about 2.5 inches, or any value between the aforementioned values.

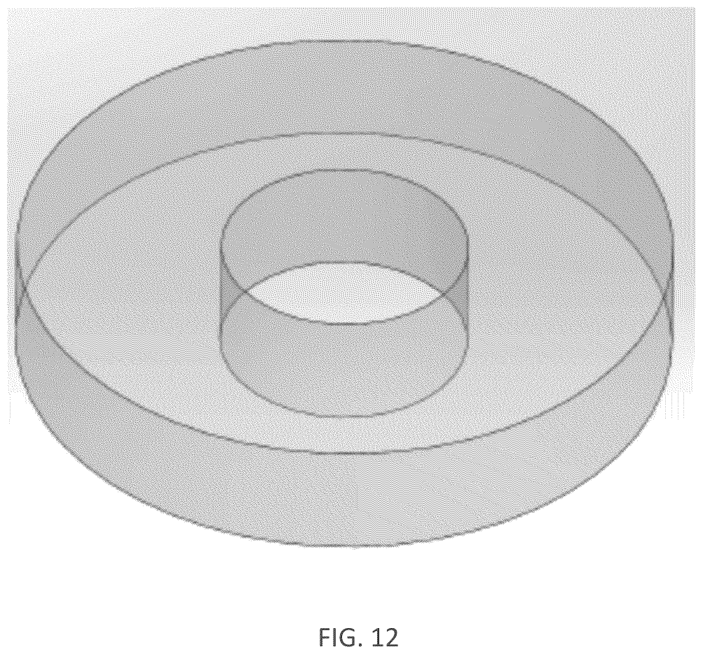

FIG. 12 illustrates another example powder ingress preventor according to some embodiments herein. In some embodiments, the washer PIP may comprise a larger outer diameter. In some embodiments, the outer diameter may be about 8 inches.

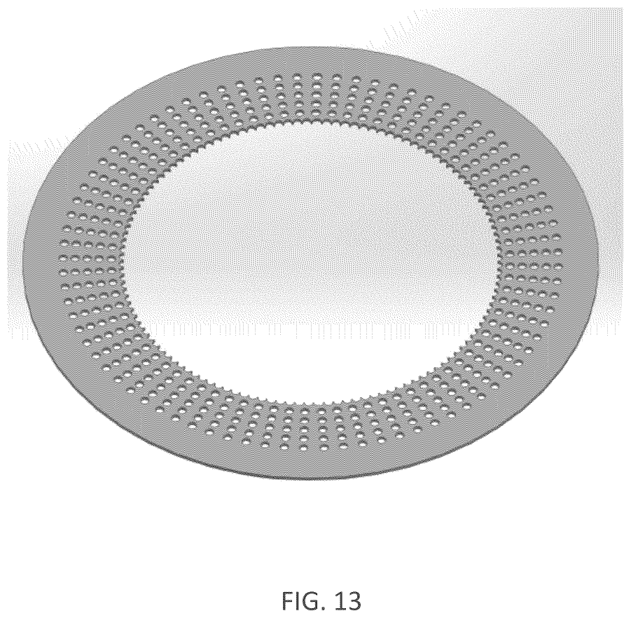

FIG. 13 illustrates another example powder ingress preventor according to some embodiments herein. In some embodiments, the PIP may comprise an annular ring with a plurality of holes through the annular ring. In some embodiments, the plurality of holes form one or more concentric circles through a surface of the washer. In some embodiments, the annular ring may comprise one or more cutouts or serrations on the interior opening of the ring.

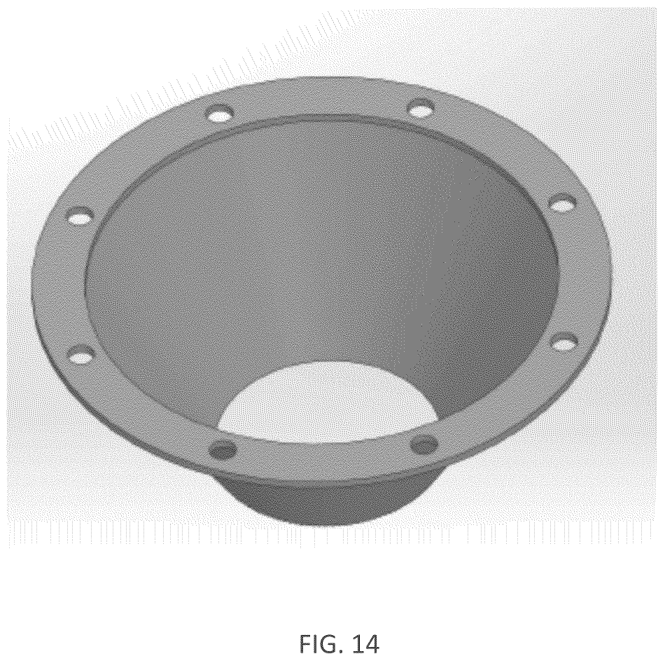

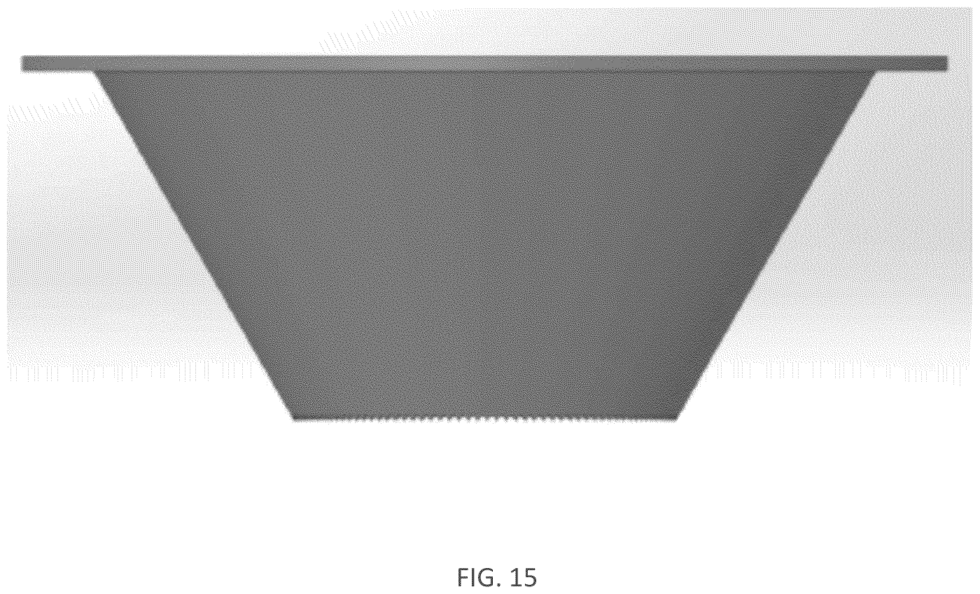

FIG. 14 illustrates another example powder ingress preventor according to some embodiments herein. FIG. 15 illustrates a side view of the example powder ingress preventor of FIG. 14. In some embodiments, the PIP may comprise an inverted cone shape with a rim. In some embodiments, the rim may comprise one or more holes through the ring. In some embodiments, the inverted cone may extend downward and radially inward to an opening at the bottom of the cone. In some embodiments, the opening may comprise one or more cutouts or serrations.

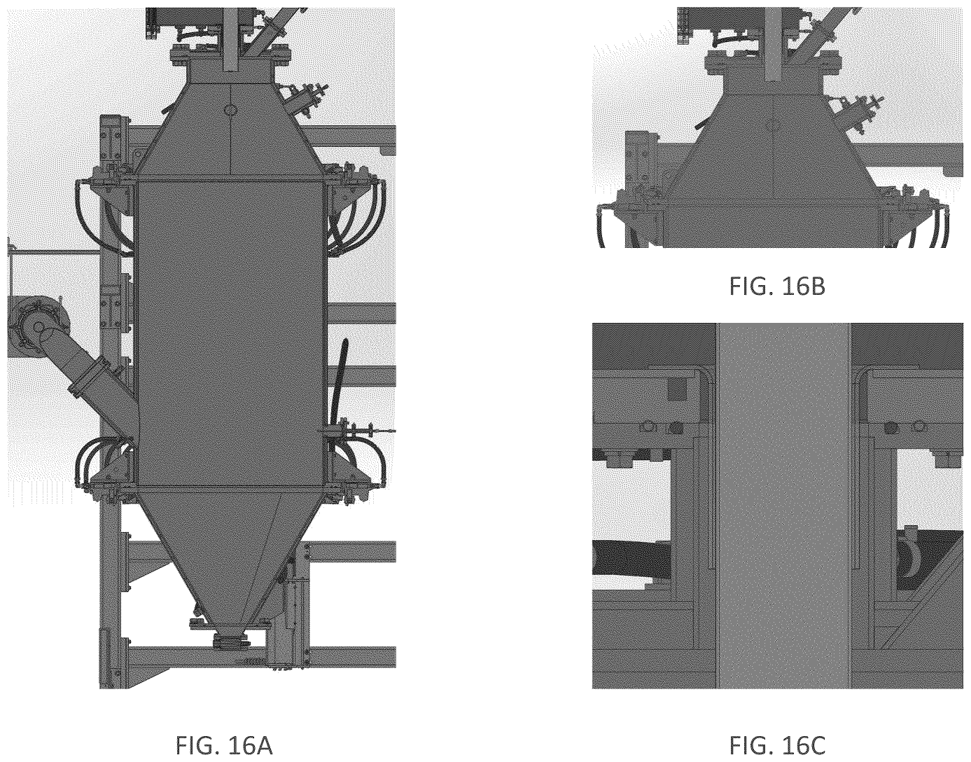

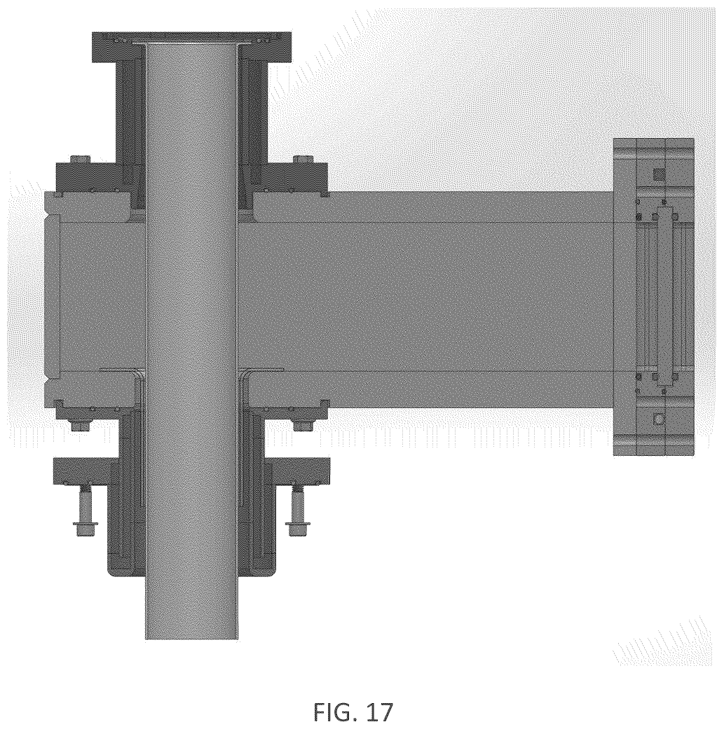

FIG. 16A-16C illustrate an example microwave plasma apparatus comprising a powder ingress preventor according to some embodiments herein. FIG. 17 illustrates an example microwave plasma apparatus comprising a waveguide and plasma applicator with a powder ingress preventor according to some embodiments herein. As noted above, in some embodiments, the PIP may comprise a sleeve piece laying in the applicator around the liner.

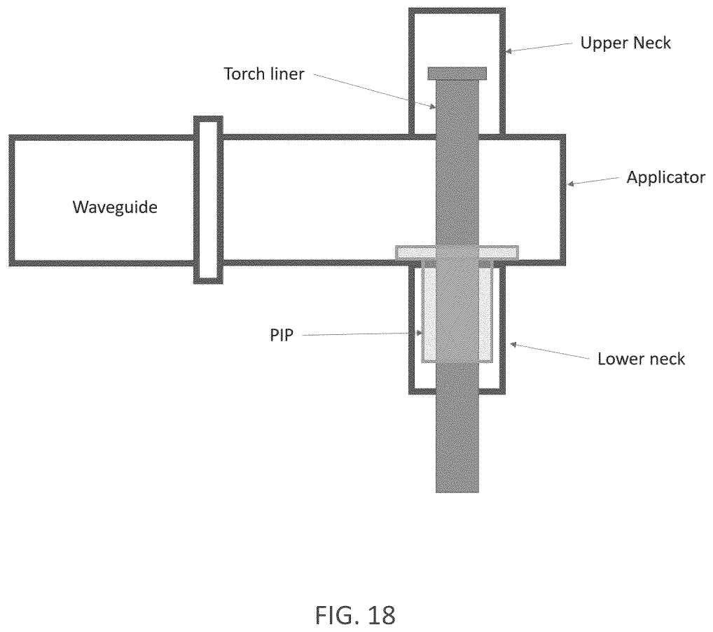

FIG. 18 illustrates an example microwave plasma apparatus comprising a waveguide and plasma applicator with a powder ingress preventor according to some embodiments herein. As illustrated in FIG. 18, a microwave plasma apparatus may comprise a core plasma tube comprising an upper neck and a lower neck, separated by a plasma applicator in communication with a waveguide configured to transmit microwave power from a microwave power source. In some embodiments, a torch liner may be provided within the core plasma tube and extending from the upper neck through the applicator and lower neck into the reaction chamber. In some embodiments, a PIP may be provided surrounding the torch liner within the applicator and/or lower neck of the core plasma tube. In some embodiments, the PIP may comprise a ring structure comprising a bearing surface and a tube. In some embodiments, the bearing surface may contact a lower surface of the applicator, while the tube may comprise an annular ring surrounding the torch liner. In some embodiments, the tube may be concentric with the core plasma tube and the torch liner. In some embodiments, the tube may comprise an opening or annulus with a diameter greater than the diameter of the torch liner, such that a gap is provided between the torch liner and PIP tube. In some embodiments, the tube of the PIP ring structure may extend downward from the applicator into the lower neck of the core plasma tube.

### EXAMPLES

### Example 1

The PIP illustrated in FIGS. 6-8 was evaluated using an O₂ plasma at 30 kW power and a pressure of about 90 psi (about 4654.34 Torr) to about 120 psi (about 6205.79 Torr), with about 20 kg of material feed input. After each test, the plasma apparatus was inspected for powder ingress. Compared to a system without a PIP, powder ingress was greatly reduced or entirely eliminated. The outer surface of the PIP had a heavy coating of powder, while the inner surface showed no signs of powder ingress. The PIP showed no signs of damage. In some embodiments, installation of a PIP in the microwave plasma apparatus requires no retuning of the plasma apparatus or process.

### Example 2

A test was conducted using 24 kW to 34 kW extended runs with Tungsten-Rhenium powder having a particle size of about 5 μm to 25 μm using the PIP of FIGS. 6-8. The powder was fed at 0.5-3.0 kg/hour through a single injector. Waveguide gas was flown at 1.5 scfm. Adding a PIP to the plasma apparatus resulted in no change in plasma stability, and no change in reflected power without additional tuning of the plasma. The PIP collected a large amount of powder and powder in the plasma applicator was drastically reduced or fully eliminated. There was a large amount of powder buildup on the inside of PIP, and on the outside of liner where the PIP overlapped.

There was more powder buildup in the lower neck of the PIP. The buildup on the interior was textured instead of a typical smooth buildup. There was increased plasma arcing on the liner.

### Additional Embodiments

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, although this invention has been disclosed in the context of certain embodiments and examples, it will be understood by those skilled in the art that the invention extends beyond the specifically disclosed embodiments to other alternative embodiments and/or uses of the invention and obvious modifications and equivalents thereof. In addition, while several variations of the embodiments of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. It should be understood that various features and aspects of the disclosed embodiments can be combined with, or substituted for, one another in order to form varying modes of the embodiments of the disclosed invention. Any methods disclosed herein need not be performed in the order recited. Thus, it is intended that the scope of the invention herein disclosed should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in several ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the invention is not to be limited to the particular forms or methods disclosed, but, to the contrary, the invention is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are in standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A microwave plasma apparatus for processing a material, comprising:
a core plasma tube;
a liner located within and concentric with the core plasma tube;
a plasma applicator; and
a ring structure located between the core plasma tube and the liner, the ring structure concentric with the core plasma tube and the liner, and the ring structure comprising:
a bearing surface, the bearing surface contacting a bottom surface of the plasma applicator; and
an opening, the opening surrounding the liner and having a diameter greater than an outer diameter of the liner.

2. The microwave plasma apparatus of claim 1, wherein the ring structure is formed of glass or quartz.

3. The microwave plasma apparatus of claim 1, wherein the ring structure comprises a single piece of material.

4. The microwave plasma apparatus of claim 1, wherein the ring structure comprises an assembly comprising two or more pieces, wherein the assembly comprises a first piece comprising a flange and a second piece comprising a tube.

5. The microwave plasma apparatus of claim 1, wherein the ring structure comprises a washer, wherein the washer comprises a plurality of holes.

6. The microwave plasma apparatus of claim 5, wherein the plurality of holes form one or more concentric circles on a surface of the washer.

7. The microwave plasma apparatus of claim 1, wherein the ring structure comprises a stack of washers.

8. The microwave plasma apparatus of claim 7, wherein the ring structure comprises a stack of two washers, three washers, or four washers.

9. The microwave plasma apparatus of claim 1, wherein the opening comprises one or more indentations or serrations.

10. The microwave plasma apparatus of claim 1, wherein the ring structure comprises an inverted cone, wherein the inverted cone comprises a rim, the rim comprising one or more holes formed through the rim, wherein the inverted cone comprises a serrated bottom opening.

11. The microwave plasma apparatus of claim 10, wherein the inverted cone comprises a serrated bottom opening.

12. A ring structure for preventing powder ingress within a microwave plasma apparatus, the ring structure comprising:
a bearing surface, the bearing surface contacting a lower surface of a plasma applicator of the microwave plasma apparatus; and
an opening, the opening the opening surrounding a liner of the microwave plasma apparatus and having a diameter greater than an outer diameter of the liner.

13. The ring structure of claim 12, wherein the ring structure is formed of glass or quartz.

14. The ring structure of claim 12, wherein the ring structure comprises a single piece of material.

15. The ring structure of claim 12, wherein the ring structure comprises an assembly comprising two or more pieces, wherein the assembly comprises a first piece comprising a flange and a second piece comprising a tube.

16. The ring structure of claim 12, wherein the ring structure comprises a washer, wherein the washer comprises a plurality of holes, wherein the plurality of holes form one or more concentric circles on a surface of the washer.

17. The ring structure of claim 12, wherein the ring structure comprises a stack of washers.

18. The ring structure of claim 17, wherein the ring structure comprises a stack of two washers, three washers, or four washers.

19. The ring structure of claim 12, wherein the opening comprises one or more indentations or serrations.

20. The ring structure of claim 12, wherein the ring structure comprises an inverted cone, the rim comprising one or more holes formed through the rim, wherein the inverted cone comprises a serrated bottom opening.
